(19) United States
(12) Patent Application Publication
(10) Pub. No.: US 2019/0369684 A1
(43) Pub. Date: Dec. 5, 2019

(54) FANLESS RAIL COOLED ELECTRONICS APPARATUS

(71) Applicant: ADC TECHNOLOGIES INC., Montreal (CA)

(72) Inventor: NIALL THOMAS DAVIDSON, LACHINE (CA)

(21) Appl. No.: 16/253,889

(22) Filed: Jan. 22, 2019

Related U.S. Application Data
(63) Continuation of application No. PCT/CA2017/050918, filed on Jul. 31, 2017.
(60) Provisional application No. 62/368,826, filed on Jul. 29, 2016.

(51) Int. Cl. G06F 1/20; F28F 9/26; H05K 7/20; F28D 15/02

(52) U.S. Cl. CPC G06F 1/206; F28F 9/26; H05K 7/20663; H05K 7/20336; H05K 7/20809; F28D 15/0275; H05K 7/20781

(57) ABSTRACT

A computer server of a type which can be cooled by installation into a cooled enclosure. The computer server notably comprises a chassis and a motherboard, the chassis being configured for engaging the motherboard. The chassis is made of a thermally conductive material and is further configured for transferring heat generated by heat generating components of the motherboard to a heat removal portion of the chassis. The heat removal portion engages a channel of the cooled enclosure when the chassis is inserted in a cooled enclosure. The chassis also have heat transmitting means such as heat pipes to aid in transferring means from the heat generating components of the motherboard to the heat removal portion.

### CROSS-REFERENCE TO RELATED APPLICATION

This application claims priority from U.S. Provisional Patent Application 62/368,826 filed on Jul. 29, 2016 and hereby incorporated by reference herein.

### BACKGROUND

The majority of contemporary rack mount electronics apparatus such as computer servers, blade servers and other apparatus use air as their primary means of removing heat, whilst convenient, air is an inefficient means of transporting heat and managing air flow and temperatures within servers and data centers is becoming increasingly complex and challenging.

Technologies described in World Intellectual Property Organization [WIPO] publications WO/2014/030046-A1, WO/2016/004531-A1 and WO/2016/004528-A1 comprises of a cooled enclosure apparatus which in cooperation with compatible rail cooled computer servers and other electronic equipment can remove heat efficiently and cost effectively without relying on air as the primary means of transporting heat.

### SUMMARY

Disclosed are electronic apparatus which can be cooled by installation into compatible cooled enclosure apparatus.

Benefits of the apparatus embodying features of the present disclosure include, but are not limited to, apparatus which has a low component count with low cost mass producible and easy to assemble components and the potential to be operated without the need for forced air cooling.

An exemplary fanless computer server is described, the computer server comprising a chassis manufactured from a thermally conductive material, for example a thermally conductive plastic, the chassis operating as a heat transmitting component transferring heat from heat generating components of a motherboard to a heat removal portion of the chassis; the chassis also providing support to the motherboard installed in the chassis. The exemplary fanless server also comprises a heat transmitting component in the form of a heatpipe assembly which is configured to transfer heat from CPUs installed on the motherboard to the heat removal portion of the chassis.

### DRAWINGS

These and other features, aspects, and advantages of the present disclosure will become better understood with regard to the following description and accompanying drawings where:

FIG. 1 shows an exploded isometric view of a computer server comprising a motherboard and a chassis in accordance with the present disclosure;

FIG. 2 shows an assembled isometric view of the computer server of FIG. 1; and

FIG. 3 shows an assembled view of the computer server of FIGS. 1 and 2 installed in a cooled enclosure.

### DESCRIPTION

It is intended that the following description and claims should be interpreted in accordance with Webster's Third New International Dictionary, Unabridged unless otherwise indicated.

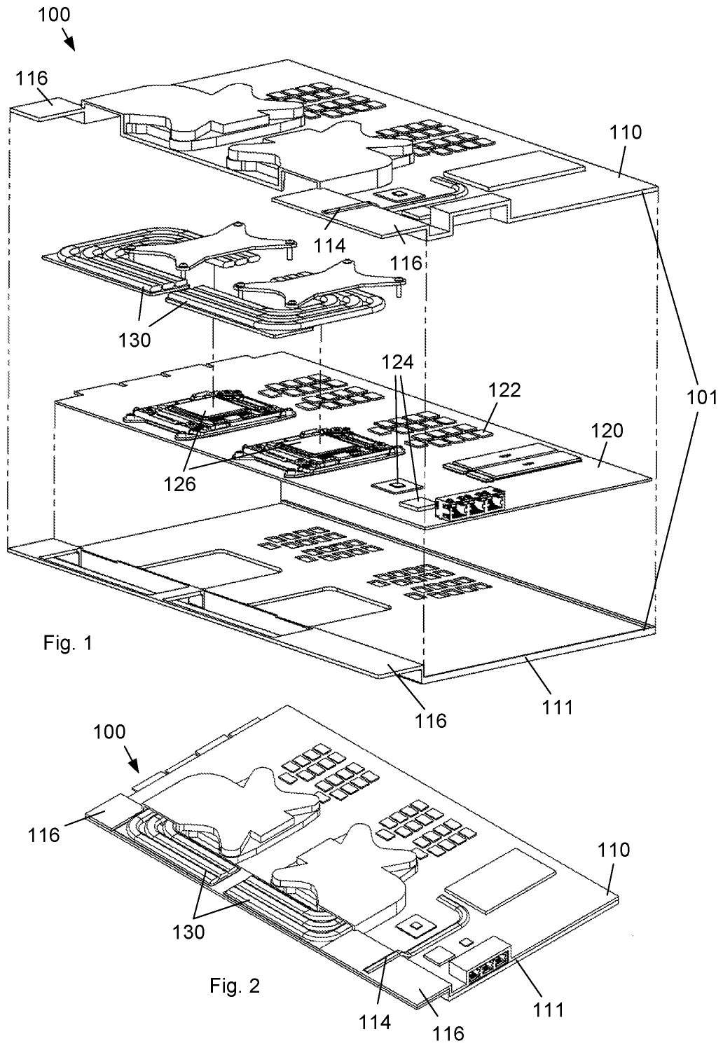

With reference to FIG. 1, a non-limiting embodiment of the computer server 100 is shown which comprises a chassis 101, a motherboard 120 and heat transfer components 130. The computer server 100 is of a type which can be cooled by installation into a cooled enclosure, the cooled enclosure being of a type similar to that described previously by this inventor in WIPO publications WO/2014/030046-A 1, WO/2016/004531-A1 and WO/2016/004528-A1 which are each incorporated herein by reference in their entirety. The described computer server 100 is intended, but not required, to be operated without a fan or necessitating air-cooling.

In this embodiment, the chassis 101 comprises an upper portion 110 and a lower portion 111, the upper portion 110 and the lower portion 111 being manufactured from a thermally conductive material and being unitary (i.e., each one of the upper and lower portions 110, 111 is made of a single component). In this embodiment, the upper and lower portions 110, 111 comprise a pattern of recesses protruding away from a surface of each one of the upper and lower portions 110, 111. The pattern of recesses generally corresponds to a pattern of protrusions of the motherboard 120, each protrusion corresponding to a heat generating component of the motherboard 120. Via the respective patterns of recesses and protrusions, the upper and lower portions 110, 111 are configured for interfitting engagement with the motherboard 120 when the upper and lower portions 110, 111 are joined together with the motherboard 120 between the upper and lower portions 110, 111. In this embodiment, the interfitting engagement between the chassis 101 comprising upper and lower portions 110, 111 and the motherboard 120 enables heat transfer between heat generating components of the motherboard 120 (e.g., memory 122 and integrated circuits 124) and the upper and lower portions 110, 111, the heat being removed from the chassis 101 at a heat removal portion 116 as further described below. In other embodiments, the chassis 101 comprising the upper portion 110 and the lower portion 111 may be configured for interfitting engagement with the pattern of protrusions of the motherboard 120 without the upper and lower portions 110, 111 comprising a pattern of recesses.

The thermally conductive material of the upper and lower portion 110, 111 of the chassis 101 may be, for example, a plastic material, a metal material, any other suitable material or any combination thereof. Non-limiting examples of suitable thermally conductive plastic materials comprise the CoolPoly range of materials manufactured by Cool Polymers (Celanese Corporation, Irving Tex.). Several polymer blends in the CoolPoly range of materials have properties suitable for the manufacture of the chassis 101, including but not limited to electromagnetic (EMI) shielding as well as thermal conductivity and other beneficial mechanical properties. Any other suitable thermally conductive plastic may be used in other embodiments. Non-limiting examples of suitable thermally conductive metals include aluminium, copper, gold, silver and the likes.

In this embodiment, the chassis 101 may further comprise interlocking means such as but not limited to living hinges, circuit board standoffs, snap fit features and the likes to ensure proper interfitting engagement and heat transfer between the upper and lower portions 110, 111 of the chassis 101 and the motherboard 120. The interlocking means may be designed (e.g., molded) directly into the chassis 101, thus reducing additional manufacturing steps and components of the chassis 101 or the interlocking means may be separate components added to the chassis 101 after manufacture of the chassis 101.

In this embodiment, heat transmitting means such as but not limited to heat pipes may be integral with, or molded directly into the, chassis 101 thereby improving heat transfer efficiency between the heat generating components of the motherboard 120 and the chassis 101 and reducing assembly steps of the chassis 101. A non-limiting example of an overmolded heat pipe 114 is shown in the upper portion 110 of the chassis 101, the overmolded heat pipe 114 aiding in efficiently transferring heat from a number of heat generating components on the motherboard 120 (e.g., integrated circuits 124) to the heat removal portion 116 of the chassis 101 by increasing heat transfer from the integrated circuits 124. The heat transmitting means such as but not limited to heat pipes may project inside a corresponding channel of the cooled enclosure or may have any other suitable configuration in other embodiments. In other non-limiting embodiments, the heat transmitting means such as but not limited to heat pipes may be distinct from the chassis 101 and not molded directly into the chassis 101. Any other suitable configuration of the heat transmitting means may be possible in other embodiments.

The heat transmitting means may comprise heat pipes, vapor chambers, thermosyphons, thermal interface materials and thermally conductive materials, composites, manufactures and apparatus such as: thermally conductive metals, examples of which include copper, aluminium, beryllium, silver, gold, nickel and alloys thereof; thermally conductive non-metallic materials, examples of which include diamond, carbon fiber, carbon nanotubes, graphene, graphite and combinations thereof; composite materials and manufactures, examples of which include graphite fiber/copper matrix composites and encapsulated graphite systems; thermally conductive filled plastics, examples of which include metal filled plastics, graphite filled plastics, carbon nanotube filled plastics, graphene filled plastics and carbon fiber filled plastics; and apparatuses such as liquid circulation, heat pumps and heat exchangers. A “heat transmitting means” is further intended to encompass any means presently existing or that is discovered in the future which transmits heat from one place to another.

In this embodiment, the heat removal portion 116 of the chassis 101 is a rail portion extending along a longitudinal direction of the computer server 100. In other non-limiting embodiments, the heat removal portion 116 may comprise a plurality of rail portions extending along a plurality of sides of the computer server 100.

In this embodiment, each one of the upper and lower portions 110, 111 is unitary and the chassis 101 may accordingly be manufactured in two halves (e.g., the upper and lower portions 110, 111) which are subsequently joined either temporarily, for example via snap fittings or any other suitable removable fastening mechanism, or permanently, for example by the use of a glue or other permanent fastening method such as ultrasonic welding. In other non-limiting embodiments, each one of the upper and lower portions 110,111 of the chassis 101 may not be unitary and may comprise several components. In yet further embodiments, the chassis 101 may comprise any number of portions (e.g., one portion or more than two portions) configured for interfitting engagement with the motherboard 120 when the portions are joined together.

With further reference to FIG. 2, in this non-limiting embodiment, the motherboard 120 fits inside the upper and lower portions 110, 111 such that, when the motherboard 120 is installed within the upper and lower portions 110, 111 of the chassis, one or more motherboard components, for example heat generating components such as memory chips 122, are brought into contact with either one of the upper and lower portions 110, 111 thereby enabling heat transfer from the memory chips 122 to the chassis 101. The chassis 101 in turn transfers heat from the heat generating components that are in contact with it to the heat removal portion 116 of the chassis 101, in this case the rail portion of the chassis 101. In some non-limiting embodiments, heat generating components which generate too much heat for the chassis 101 may also be further cooled via other means such as heat transmitting means which can be integral with the chassis 101 (e.g. overmolded heatpipes or other thermally conductive materials) or distinct from the chassis 101 and in proximity or contact with the heat generating components. In some non-limiting examples, CPUs 126 are further cooled using heat transmitting means 130 installed within the chassis 101 and distinct from the chassis 101, and the integrated circuits 124 are further cooled using heat transmitting mean 114 integral with the chassis 101.

As the upper and lower portions 110, 111 of the chassis 101 can contact and remove heat from heat generating components on both sides of the motherboard 120 including but not limited to, RAM, CPUs, chipsets and the likes, heat generating components can be populated on both sides of the motherboard 120. This has the benefit of enabling more area of the motherboard 120 to be used when compared to existing air-cooled server motherboard designs which may be limited to placing the majority of heat generating components on just one side of the motherboard.

In one non-limiting embodiment, in order to improve the thermal transfer between the heat generating components of the motherboard 120 and the upper and lower portions 110, 111 of the chassis 101, a thermal interface material may be introduced between the upper and lower portions 110, 111 of the chassis 101 and the motherboard 120. In this case, the chassis 101 may be manufactured in a multi-shot molding machine, molding a thermally conductive elastomer to the motherboard contacting side of each one of the upper and lower portions 110, 111. A suitable thermally conductive elastomer may also be found amongst the CoolPoly range of materials. In other non-limiting embodiments, gap pads, thermal grease and the likes may also be used.

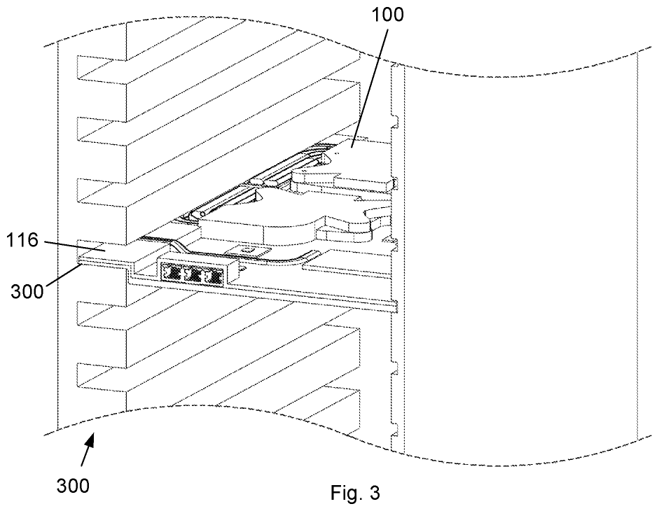

With further reference to FIG. 3, the computer server 100 may be installed within a compatible cooled enclosure 300 by engaging the rail portion 116 of the computer server 100 within a channel 310 of the cooled enclosure 300. Heat transmitted via the chassis 101 can be removed via the cooled enclosure 300 and thus, in this non-limiting example, the integrated circuits 124 and memory chips 122 as well as other heat generating components brought into contact with the chassis 101 can be cooled. See WIPO publications WO/2014/030046-A1, WO/2016/004531-A1 and WO/2016/004528-A1 for further information on how the rail portion 116 can be configured to be cooled by a compatible cooled enclosure.

The motherboard 120 may be held in place by the chassis 101 making use of snap fit features (not shown) and other simple mechanisms well known to those skilled in the art of plastics design. Alternative fastening means such as screws or adhesives may also be used in other embodiments.

Heat transmitting components in the form of heat pipe assemblies 130 are also shown, the heat pipe assemblies 130 transferring waste heat from CPUs 126 to a proximity of the heat removal portion 116 of the chassis 101. Suitable heat pipe assemblies are notably described in WIPO publication WO/2016/004531-A1. The heat pipe assemblies 130 allow the high thermal loads developed by the CPUs 126 to be transmitted to the proximity to the heat removal portion 116 without being conducted through the upper and lower portions 110, 111 of the chassis 101 and potentially causing damage to the upper and lower portions 110, 111 of the chassis 101.

While the computer server 100 shown and described is of a type which can be cooled by installation into a cooled enclosure as described in WIPO publications WO/2014/030046-A1, WO/2016/004531-A1 and WO/2016/004528-A1, it is to be understood that the described embodiments are merely illustrative of the many possible specific arrangements that can be devised in application of the principles of the present disclosure and that the teachings of the present disclosure can be applied to computer servers and other electronic apparatus cooled via other means. Numerous and varied other arrangements can be devised by those of ordinary skill in the art without departing from the scope and spirit of the present disclosure. Furthermore it is not intended that the teachings of the present disclosure be limited to computer servers such as described and can be applied to network switches, routers, storage arrays, HPC servers and any other suitable electronic equipment.

1-15. (canceled)

16. Rack-mountable equipment for installation in a cooled enclosure, the rack-mountable comprising:
a. A chassis; and
b. A motherboard comprising a plurality of heat generating components constituting a pattern of protrusions,
the chassis being configured for providing support to the motherboard when inserted in an enclosure, the chassis being further configured for enabling an interfitting engagement with the pattern of protrusions of the motherboard when the motherboard is installed in the chassis, the interfitting engagement enabling a transfer of heat between the plurality of heat generating components and the chassis, the chassis being further configured for transferring the heat received by the chassis to a heat removal portion of the chassis.

17. The rack-mountable equipment of claim 16, wherein the interfitting engagement between the chassis and the motherboard enables an exchange of heat sufficient for the purpose of cooling the motherboard when the chassis is inserted in the enclosure.

18. The rack-mountable equipment of claim 16, wherein the heat removal portion comprises a rail portion extending along a longitudinal direction of the chassis, the longitudinal portion being configured to mate with a channel in the enclosure when the chassis is inserted in the enclosure along the longitudinal direction.

19. The rack-mountable equipment of claim 16, wherein the chassis is made at least in part of a thermally conductive material.

20. The rack-mountable equipment of claim 19, wherein the thermally conductive material is a plastic material.

21. The rack-mountable equipment of claim 19, wherein the thermally conductive material is a metal.

22. The rack-mountable equipment of claim 1, further comprising at least one heat transmitting mean to transfer the heat received by the chassis to the heat removal portion of the chassis.

23. The rack-mountable equipment of claim 22, wherein the at least one heat transmitting mean is integral with the chassis.

24. The rack-mountable equipment of claim 23, wherein the integral at least one heat transmitting mean is molded in the chassis.

25. The rack-mountable equipment of claim 22, wherein the at least one heat transmitting mean is distinct from the chassis.

26. The rack-mountable equipment of claim 22, wherein the at least one heat transmitting mean is a heat pipe.

27. The rack-mountable equipment of claim 26, wherein the heat pipe projects inside a channel of the enclosure.

28. The rack-mountable equipment of claim 16, wherein the heat removal portion of the chassis extends along more than one side of the chassis.

29. The rack-mountable equipment of claim 16, wherein the chassis comprise two unitary components.

30. The rack-mountable equipment of claim 16, wherein a motherboard facing side of the chassis comprises a thermally conductive elastomer.

31. Rack-mountable equipment for installation in a cooled enclosure, the rack-mountable equipment comprising:
a. A chassis comprising a heat removal portion; and
b. A motherboard comprising a plurality of heat generating components,
the heat removal portion contacting the cooled enclosure when the rack-mountable equipment is installed in the cooled enclosure,
the chassis being configured for providing support to the motherboard when inserted in the cooled enclosure, the chassis being made at least in part of a thermally conductive material and enabling a transfer of heat from the plurality of heat generating components to a heat removal portion of the chassis and an exchange of heat between the heat removal portion of the chassis and the cooled enclosure sufficient for the purpose of cooling the motherboard.

32. The chassis of claim 29, wherein at least one of the unitary components is shaped by a single manufacturing step to enable the interfitting engagement of at least two of the protrusions that comprise the pattern of protrusions of the motherboard.

33. The chassis of claim 16, wherein the chassis comprises a casting and the interfitting engagement with the pattern of protrusions on the motherboard is enabled by cast features corresponding to the pattern of protrusions.

34. The chassis of claim 33, wherein the cast features enable interfitting engagement with at least two of the protrusions that comprise the pattern of protrusions of the motherboard.

35. The chassis of claim 16, wherein the chassis comprises an injection molded component whereby the interfitting engagement with the pattern of protrusions is enabled by molded features corresponding to the pattern of protrusions.

36. The chassis of claim 35, wherein the molded features enable interfitting engagement with at least two of the protrusions that comprise the pattern of protrusions of the motherboard.
